(19) United States
(12) Patent Application Publication
(10) Pub. No.: US 2021/0091248 A1
(43) Pub. Date: Mar. 25, 2021

(54) BACK PANEL OF SOLAR CELL AND METHOD FOR MANUFACTURING THE SAME, AND METHOD FOR MANUFACTURING SOLAR CELL MODULE

(71) Applicant: NAN YA PLASTICS CORPORATION, TAIPEI (TW)

(72) Inventors: TE-CHAO LIAO, TAIPEI (TW); CHING-YAO YUAN, TAIPEI (TW); Ming-lang Liu, TAIPEI (TW)

(21) Appl. No.: 16/839,492

(22) Filed: Apr. 3, 2020

(30) Foreign Application Priority Data
Sep. 24, 2019 (TW) 108134488

(51) Int. Cl. H01L 31/048; H01L 31/049; H01L 31/0216

(52) U.S. Cl. CPC H01L 31/0481; H01L 31/02167; H01L 31/049

(57) ABSTRACT

A back panel of a solar cell, a method for manufacturing the back panel, and a method for manufacturing a solar cell module are provided. A method of manufacturing a back panel of a solar cell includes steps below. A polyester layer is provided. A reflective laminate is disposed on one surface of the polyester layer and a protective layer is disposed on another surface of the polyester layer to obtain the back panel of the solar cell. The reflective laminate includes a reflective packaging layer and a connecting layer. The connecting layer is sandwiched between the polyester layer and the reflective packaging layer. A material of the reflective packaging layer is ethylene vinyl acetate. A material of the connecting layer is polyolefin.

### CROSS-REFERENCE TO RELATED PATENT APPLICATION

This application claims the benefit of priority to Taiwan Patent Application No. 108134488, filed on Sep. 24, 2019. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a back panel of a solar cell and a method for manufacturing the same, and a method for manufacturing a solar cell module, and more particularly to the back panel of a solar cell and the method for manufacturing the same, and the method for manufacturing the solar cell module which includes a packaging layer.

### BACKGROUND OF THE DISCLOSURE

Generally, a back panel is a component of a solar cell module which has the largest contact area with the external environment. The back panel not only supports the entire solar cell module, but also isolates the solar cell from the external environment so as to protect the solar cell.

Referring to FIG. 1, FIG. 1 is a side schematic view of a back panel of a conventional solar cell. In the conventional technology, the back panel of the solar cell includes a polyester layer 7, a reflective layer 8, and a protective layer 9. The reflective layer 8 is disposed on a surface of the polyester layer 7. The reflective layer 8 is adjacent to the solar cell, so that a dispersed light can be reflected towards the solar cell by the reflective layer 8, which increases a utilization ratio of light and an efficiency of light conversion. The protective layer 9 is disposed on another surface of the polyester layer 7 opposite to the reflective layer 8. The protective layer 9 is a component of the back panel having the largest contact area with the external environment. The protective layer 9 can prevent the solar cell from contacting the external environment so as to protect the solar cell.

An ethylene vinyl acetate (EVA) copolymer film, a solar cell, another EVA copolymer film, and a glass substrate are sequentially disposed on the reflective layer 8 of the back panel so as to assemble a solar cell module. The solar cell will be completely covered by the two EVA copolymer films which are respectively disposed on two sides of the solar cell after a packaging process so that the solar cell can be protected. Light is allowed to permeate the glass substrate and to be used by the solar cell.

According to the method for manufacturing the solar cell module previously mentioned, the step of disposing the EVA copolymer film on the back panel should be executed twice, resulting in a complicated process and a high production cost. When an amount of steps involved in the process is increased, a defect rate of the process is usually increased. Therefore, for a downstream company, if a process for assembling the solar cell module can be simplified appropriately, the production efficiency can be increased and the production cost can be reduced.

### SUMMARY OF THE DISCLOSURE

In response to the above-referenced technical inadequacies, the present disclosure provides a back panel of a solar cell and a method for manufacturing the same, and a method for manufacturing a solar cell module.

In one aspect, the present disclosure provides a method of manufacturing a back panel of a solar cell. A polyester layer is provided. A reflective laminate is disposed on one surface of the polyester layer and a protective layer is disposed on another surface of the polyester layer to obtain the back panel of the solar cell. The reflective laminate includes a reflective packaging layer and a connecting layer. The connecting layer is sandwiched between the polyester layer and the reflective packaging layer. A material of the reflective packaging layer is ethylene vinyl acetate. A material of the connecting layer is polyolefin.

In certain embodiments, the present disclosure provides a method of manufacturing a back panel of a solar cell. The material of the connecting layer contains 30 wt % to 60 wt % of polypropylene and 40 wt % to 70 wt % of polyethylene.

In certain embodiments, the present disclosure provides a method of manufacturing a back panel of a solar cell. The reflective packaging layer and the connecting layer are formed integrally by a co-extrusion process.

In certain embodiments, the present disclosure provides a method of manufacturing a back panel of a solar cell. The material of the reflective packaging layer contains 10 wt % to 35 wt % of reflective fillers.

In certain embodiments, the present disclosure provides a method of manufacturing a back panel of a solar cell. Crosslinking agents are not included in the material of the reflective packaging layer.

In certain embodiments, the present disclosure provides a method of manufacturing a back panel of a solar cell. An adhesive layer is sandwiched between the polyester layer and the connecting layer, and another adhesive layer is sandwiched between the polyester layer and the protective layer.

In another aspect, the present disclosure provides a method for manufacturing a solar cell module. A polyester layer is provided. A reflective laminate is disposed on one surface of the polyester layer and a protective layer is disposed on another surface of the polyester layer to obtain a back panel. The reflective laminate includes a reflective packaging layer and a connecting layer. The connecting layer is sandwiched between the polyester layer and the reflective packaging layer. A material of the reflective packaging layer is ethylene vinyl acetate. A material of the connecting layer is polyolefin. A solar cell is disposed between a packaging layer and the reflective packaging layer of the back panel to obtain the solar cell module.

In yet another aspect, the present disclosure provides a back panel of a solar cell. The back panel of the solar cell includes a polyester layer, a reflective laminate, and a protective layer. The reflective laminate is disposed on the polyester layer. The reflective laminate includes a connecting layer and a reflective packaging layer. The connecting layer is sandwiched between the polyester layer and the reflective packaging layer. A material of the connecting layer is polyolefin. A material of the reflective packaging layer is ethylene vinyl acetate. The protective layer is disposed on the polyester layer.

In certain embodiments, a thickness of the reflective packaging layer is from 200 μm to 500 μm.

In certain embodiments, a thickness of the connecting layer is from 30 μm to 100 μm.

Therefore, the back panel of the solar cell, the method for manufacturing the back panel, and the method for manufacturing the solar cell module have the technical features of “the reflective laminate is disposed on one surface of the polyester layer” and “the reflective laminate includes a reflective packaging layer and a connecting layer”, so that the reflective laminate has a high reflective property and can serve as a packaging material. The method for manufacturing the solar cell module can be simplified, which results in a high production efficiency and a low production cost.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a side schematic view of a back panel of a conventional solar cell.

FIG. 2 is an exploded view of a conventional solar cell module.

FIG. 3 is a side schematic view of a back panel of the solar cell of the present disclosure.

FIG. 4 is a flowchart of a method for manufacturing the back panel of the solar cell of the present disclosure.

FIG. 5 is a flowchart of a method for manufacturing the solar cell module of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

The present disclosure provides a back panel of a solar cell to solve the problems of a complicated process, a high process cost, and a high defect rate existing in a conventional manufacturing process. In the present disclosure, a reflective laminate is included in the back panel of the solar cell. The reflective laminate includes an EVA copolymer film, so that a step of disposing the EVA copolymer film on the back panel can be omitted. Therefore, the process of assembling the solar cell module for the downstream company can be simplified, and the production cost and the product defect rate of the process can be reduced. In addition, the reflective laminate has a good reflective property so that a dispersed light can be reflected towards the solar cell. Accordingly, a utilization ratio of light and an efficiency of light conversion of the solar cell can be enhanced.

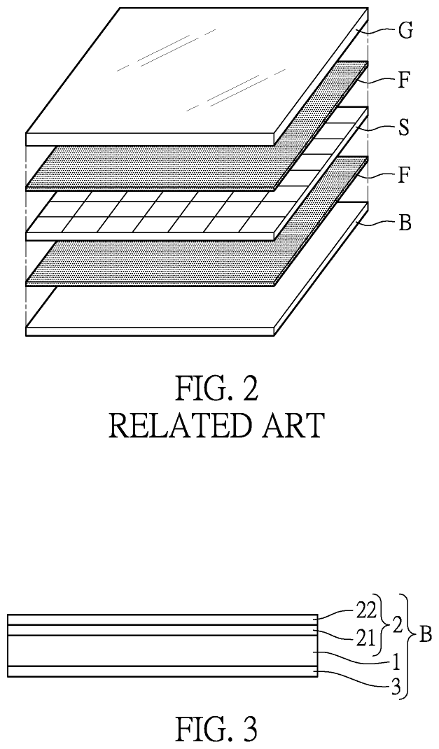

Referring to FIG. 2, FIG. 2 is an exploded view of a conventional solar cell module. The solar cell module includes a glass substrate G, an EVA copolymer film F, a solar cell S, another EVA copolymer film F, and the back panel B. Various solar cells are available in the market, such as crystalline silicon solar cell or thin-film solar cell. The back panel B of the present disclosure can be applied to the various solar cells available in the market, but the present disclosure is not limited thereto.

In the solar cell module, the two EVA copolymer films F are disposed on two opposite surfaces of the solar cell S and serve as a packaging material. The solar cell S is completely covered by the two EVA copolymer films F to protect the solar cell S. The glass substrate G is disposed on a surface of the solar cell S which receives more light. The glass substrate G can prevent the solar cell S from contacting substances in the external environment, so that the light conversion efficiency of the solar cell S is not negatively affected. The back panel B is disposed on a surface of the solar cell S opposite to the glass substrate G. A more specific illustration of the back panel B is provided below.

Referring to FIG. 3, FIG. 3 is a side schematic view of the back panel of the solar cell. In an embodiment, the back panel B of the solar cell includes a polyester layer 1, a reflective laminate 2, and a protective layer 3. A material of the polyester layer 1 is polyethylene terephthalate (PET), but is not limited thereto. The reflective laminate 2 is disposed on one surface of the polyester layer 1. A dispersed light can be reflected towards the solar cell by the reflective laminate 2 so that the utilization ratio of light and a light conversion rate of the solar cell S can be increased. In addition, the reflective laminate 2 can directly serve as a packaging material, hence, the reflective laminate 2 is beneficial for simplifying the process of packaging the solar cell S. The protective layer 3 is disposed on another surface of the polyester layer 1. The protective layer 3 has resistance to erosion so that the polyester layer 1, the reflective laminate 2, and the solar cell S are protected from being eroded by the external environment.

Specifically, the reflective laminate 2 includes a connecting layer 21 and a reflective packaging layer 22. The connecting layer 21 is sandwiched between the polyester layer 1 and the reflective packaging layer 22. The reflective packaging layer 22 is disposed on the polyester layer 1 via the connecting layer 21. A material of the connecting layer 21 is polyolefin. In the embodiment, the material of the connecting layer 21 contains 30 wt % to 60 wt % of polypropylene and 40 wt % to 70 wt % of polyethylene. By adjusting a ratio of polypropylene and polyethylene contained in the connecting layer 21, the reflective packaging layer 22 can be firmly disposed on the polyester layer 1 via the connecting layer 21, and a weather resistance and heat tolerance of the connecting layer 21 can also be enhanced. Accordingly, a service life of the back panel B can be extended.

Polypropylene contained in the connecting layer 21 can be at least one of a propylene homopolymer (PP-H), a propylene block copolymer (PP-B), and a polypropylene random copolymer (PP-R). In a preferable embodiment, polypropylene contained in the connecting layer 21 is the propylene homopolymer.

Polyethylene contained in the connecting layer 21 can be an ethylene homopolymer, an ethylene copolymer, or a combination thereof. The ethylene homopolymer is a polymer solely polymerized from ethylene. The ethylene copolymer is a polymer polymerized from ethylene and other one or more monomers. Polyethylene can be classified into a high density polyethylene (HDPE), a low density polyethylene (LDPE), a linear low density polyethylene (LLDPE), and a metallocene polyethylene (mPE), but are not limited thereto. In a preferable embodiment, polyethylene contained in the connecting layer 21 is a linear polyethylene.

In addition, the reflective packaging layer 22 is disposed on a surface adjacent to the solar cell S. The reflective packaging layer 22 has a high reflective property, so that a dispersed light can be reflected towards the solar cell S by the reflective packaging layer 22, and as a result, the utilization ratio of light and the efficiency of light conversion of the solar cell S can be increased. The reflective packaging layer 22 includes 10 wt % to 35 wt % of a reflective filler to increase the reflective property of the reflective packaging layer 22. The reflective filler can be titanium dioxide, silicon dioxide, barium sulfate, calcium carbonate, montmorillonite (MMT), aluminium paste, Mica powder, or a combination thereof, but is not limited thereto. In a preferable embodiment, the reflective filler is titanium dioxide. By including titanium dioxide, the utilization ratio of light and the light conversion rate of the solar cell S can be increased, and the weather resistance of the reflective packaging layer 22 can be enhanced, and as a result, the service life of the solar cell module can be extended.

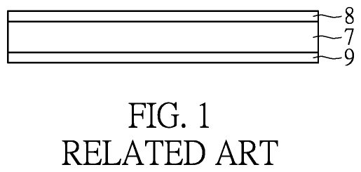

In addition, the material of the reflective packaging layer 22 further includes 14 wt % to 28 wt % of ethylene vinyl acetate copolymer. Therefore, the reflective packaging layer 22 can be used to package the solar cell S and can serve as a packaging layer. In other words, the reflective packaging layer 22 possesses functions of both the reflective layer 8 (as shown in FIG. 1) and the EVA copolymer film of the conventional back panel. That is, the reflective packaging layer 22 can reflect light towards the solar cell S and can be used to package the solar cell S, hence, the process for assembling the solar cell module can be simplified.

Compared with the reflective layer 8 of the conventional back panel (as shown in FIG. 1), the reflective packaging layer 22 of the present disclosure is closer to the solar cell S. Therefore, an optical path between the reflective packaging layer 22 and the solar cell S of the present disclosure can be shortened, and a utilization ratio of light and the light conversion rate can therefore be increased.

In the embodiment, the reflective laminate 2 of the present disclosure is formed by a co-extrusion process. In other words, the connecting layer 21 and the reflective packaging layer 22 are formed integrally, and no viscose or adhesive layer is required to be disposed therebetween. Accordingly, the method for assembling the solar cell module is simplified.

In a preferable embodiment, the material of the reflective packaging layer 22 is without any crosslinking agent. When the solar cell module is assembled, a crosslinking agent in the EVA copolymer film F can also be shared to crosslink the material of the reflective packaging layer 22, so that the solar cell S can be packaged and be covered by the EVA copolymer film F and the reflective packaging layer 22. Therefore, the crosslinking agent becoming ineffective due to aging after being opened for a long time can be prevented.

The protective layer 3 can be formed onto the polyester layer 1 by a coating process. Therefore, a coating of a viscose or a disposition of an adhesive layer is not necessarily in the step of forming the protective layer 3 of the present disclosure. That is, a step of complex processing can be omitted and a production cost can also be reduced. In addition, a problem of weakened adhesive force of a viscose or an adhesive layer caused by a permeation of water vapor can be solved. Moreover, the protective layer 3 can also be disposed on the polyester layer 1 by a laminating process so that the protective layer 3 can have a strong structural strength to protect the solar cell S.

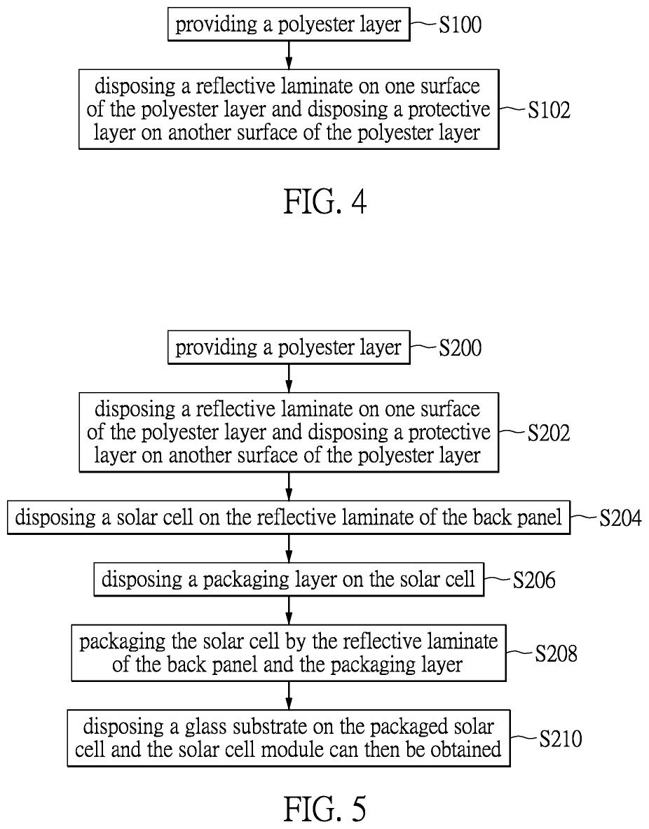

Referring to FIG. 4, FIG. 4 is a flow chart of the method for manufacturing the back panel of the solar cell. In step S100, the polyester layer 1 is provided firstly. In step S102, the reflective laminate 2 is disposed on one surface of the polyester layer 1. The specific structure of the reflective laminate 2 is previously mentioned and is not repeated herein. The protective layer 3 is disposed on another surface of the polyester layer 1 opposite to the reflective laminate 2 to obtain the back panel of the solar cell S. The disposing sequence of the reflective laminate 2 and the protective layer 3 in step S102 is not limited thereto. In other words, the reflective laminate 2 can be disposed on the polyester layer 1 after disposing of the protective layer 3; similarly, the protective layer 3 can also be disposed on the polyester layer 1 after disposing of the reflective laminate 2. Both of the disposing sequence mentioned above is within the scope of the present disclosure.

According to the method for manufacturing the back panel of the solar cell, the reflective laminate 2 of the present disclosure has a high reflective property and can serve as a packaging material. Therefore, the process for assembling the solar cell module can be simplified, and the utilization ratio of light and the efficiency of light conversion of the solar cell S can be increased.

Referring to FIG. 5, FIG. 5 is a flowchart of the method for manufacturing the solar cell module. Step S200 and step S202 in the method for manufacturing the solar cell module are similar to step S100 and step S102 in the method for manufacturing the back panel. That is, the polyester layer 1 is provided firstly (step S200). The reflective laminate 2 is disposed on one surface of the polyester layer 1 and the protective layer 3 is disposed on another surface of the polyester layer 1, so as to obtain the back panel B. Subsequently, a solar cell S is disposed on the reflective packaging layer 22 of the back panel B (step S204). A packaging layer is disposed on the solar cell S (step S206). Then, the solar cell S is packaged and is covered between the reflective packaging layer 22 of the back panel B and the packaging layer (i.e., the ethylene vinyl acetate copolymer film F) (step S208). A glass substrate G is disposed on the packaged solar cell S and the solar cell module can then be obtained (step S210).

According to the method for manufacturing the solar cell module of the present disclosure, the solar cell S can be packaged by disposing the packaging layer (the EVA copolymer film F) on the back panel B only once. Therefore, the time and the cost taken to assemble the solar cell module can be reduced and the product defect rate of the solar cell module can also be decreased.

In conclusion, the back panel of the solar cell, the method for manufacturing the back panel, and the method for manufacturing the solar cell module have the technical features of “the reflective laminate 2 is disposed on one surface of the polyester layer 1” and “the reflective laminate 2 includes a reflective packaging layer 22 and a connecting layer 21”, so that the reflective laminate 2 has a high reflective property and can serve as a packaging material. The method for manufacturing the solar cell module can be simplified, which results in a high production efficiency and low production cost.

Further, the back panel of the solar cell, the method for manufacturing the back panel, and the method for manufacturing the solar cell module have the technical feature of “the material of the connecting layer 21 contains 30 wt % to 60 wt % of polypropylene and 40 wt % to 70 wt % of polyethylene”, so that the reflective packaging layer 22 can be firmly disposed on the polyester layer 1 and the back panel B of the solar cell has a good heat-tolerance property and a good weather-resistance property.

Furthermore, the back panel of the solar cell, the method for manufacturing the back panel, and the method for manufacturing the solar cell module have the technical feature of “the reflective packaging layer 22 and the connecting layer 21 are formed integrally”, so that the method for manufacturing the back panel B of the solar cell can be simplified and usage of the viscose and the adhesive layer can be excluded.

Moreover, the back panel of the solar cell, the method for manufacturing the back panel, and the method for manufacturing the solar cell module have the technical feature of “the material of the reflective packaging layer 22 contains 10 wt % to 35 wt % of the reflective filler”, so that the optical path between the reflective packaging layer 22 and the solar cell S can be shortened and the light conversion rate of the solar cell S can be increased.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method of manufacturing a back panel of a solar cell, comprising:
providing a polyester layer; and
disposing a reflective laminate on one surface of the polyester layer and disposing a protective layer on another surface of the polyester layer to obtain the back panel of the solar cell;
wherein the reflective laminate includes a reflective packaging layer and a connecting layer, the connecting layer is sandwiched between the polyester layer and the reflective packaging layer, a material of the reflective packaging layer is ethylene vinyl acetate, and a material of the connecting layer is polyolefin.

2. The method according to claim 1, wherein the material of the connecting layer contains 30 wt % to 60 wt % of polypropylene and 40 wt % to 70 wt % of polyethylene.

3. The method according to claim 1, wherein the reflective packaging layer and the connecting layer are formed integrally by a co-extrusion process.

4. The method according to claim 1, wherein the material of the reflective packaging layer contains 10 wt % to 35 wt % of reflective fillers.

5. The method according to claim 1, wherein a crosslinking agent is not included in the material of the reflective packaging layer.

6. The method according to claim 1, wherein an adhesive layer is sandwiched between the polyester layer and the connecting layer, and another adhesive layer is sandwiched between the polyester layer and the protective layer.

7. A method for manufacturing a solar cell module, comprising:
providing a polyester layer;
disposing a reflective laminate on one surface of the polyester layer and disposing a protective layer on another surface of the polyester layer to obtain a back panel; wherein the reflective laminate includes a reflective packaging layer and a connecting layer, the connecting layer is sandwiched between the polyester layer and the reflective packaging layer, a material of the reflective packaging layer is ethylene vinyl acetate, and a material of the connecting layer is polyolefin; and
disposing a solar cell between a packaging layer and the reflective packaging layer of the back panel to obtain the solar cell module.

8. A back panel of a solar cell, comprising:
a polyester layer;
a reflective laminate disposed on the polyester layer; wherein the reflective laminate includes a connecting layer and a reflective packaging layer, the connecting layer is sandwiched between the polyester layer and the reflective packaging layer, a material of the connecting layer is polyolefin, and a material of the reflective packaging layer is ethylene vinyl acetate; and
a protective layer disposed on the polyester layer.

9. The back panel of the solar cell according to claim 8, wherein a thickness of the reflective packaging layer is from 200 μm to 500 μm.

10. The back panel of the solar cell according to claim 8, wherein a thickness of the connecting layer is from 30 μm to 100 μm.
